(19) United States
(12) Patent Application Publication
(10) Pub. No.: US 2004/0173808 A1
(43) Pub. Date: Sep. 9, 2004

(54) Flip-chip like light emitting device package

(76) Inventor: Bor-Jen Wu, Taipei (TW)

Correspondence Address: LAW OFFICES OF CLEMENT CHENG, 17220 NEWHOPE STREET #127, FOUNTAIN VALLEY, CA, 92708, US

(21) Appl. No.: 10/384,014

(22) Filed: Mar. 7, 2003

(51) Int. Cl. H01L 33/00

(52) U.S. Cl. 257/99; 257/98; 257/100

(57) ABSTRACT

A flip-chip like light emitting device package is provided. The present flip-chip like light emitting device package includes a transparent substrate having a first surface with a recess formed thereon, and a light emitting diode is placed in the recess. The light emitting diode emits light toward the first surface like the way a flip-chip type die illuminating, and thus not obstructed with a bonding pad formed on the light emitting diode. The light-emitting area is enlarged and the illuminating intensity is improved. In addition, the light emitting diode is placed in the recess so as to reduce the thickness of a molding compound encapsulating the light emitting diode.

### BACKGROUND OF THE INVENTION

1. Field of the Invention

The present invention relates to a semiconductor light emitting device package, and more particularly to a flip-chip like light emitting device package, which emits light in the way like a flip-chip type die illuminating.

2. Description of the Prior Art

The semiconductor light emitting device is a semiconductor device, which can be used to convert electrical energy into light. The semiconductor light emitting device is composed of semiconductor materials with different conductivity types such as N-type and P-type semiconductor material. In the N-type semiconductor material, the electrons in the outer shell of atoms can move freely as the carriers of current. The N-type semiconductor materials include the elements of the V group such as phosphorous (P), arsenic (As), antimony (Sb) and nitrogen (N) etc. The carrier in the N-type semiconductor material is the so-called donor. On the other hand, in the P-type semiconductor materials, the atoms possess holes because of lack of electrons, where the holes can also be the carriers. The P-type semiconductor materials include the elements of the III group such as aluminum (Al), gallium (Ga), indium (In), etc. The carrier in the P-type semiconductor material is the so-called acceptor.

As the N-type and P-type semiconductor materials joins to form a composite material, the electrons and the holes would redistribute in the composite material where the PN junction is formed between the N-type and P-type materials. The carriers in the materials with different conductivity types would cross the PN junction when the forward bias is applied to the electrodes on the composite material. In another word, the basic principle of the light emitting diode is that the holes in P-type material and the electrons in N-type material are combined in the neighborhood of the PN junction and the energy is released in photons under forward bias.

FIG. 1A is a schematic cross-sectional view of a conventional blue light emitting diode package. FIG. 1B is a schematic top view of the conventional blue light emitting diode. As shown in FIG. 1A, in the conventional blue light emitting diode package 10, a sapphire substrate 102 of a blue light emitting diode is placed on an opaque substrate 100. An adhesive material 101, for example epoxy, is used for attaching the blue light emitting diode to the opaque substrate 100. An N-type gallium nitride (n-GaN) 104 is provided on the surface of the sapphire substrate 102. A P-type gallium nitride (P-GaN) 106 for forming a P-type mesa is provided on the N-type GaN 104 and covers a portion of the surface of the N-GaN 104. The upper surface of the P-type mesa 106 is covered completely by a P-type transparent metal electrode 108 of combined nickel oxide/gold structure. An N-type bonding pad 110 and a P-type bonding pad 112 act as joints for electrical connection while wire bonding performed. The N-type bonding pad 110 is disposed on the exposed surface of the N-GaN 104 and electrically couples to a first electrode 114 patterned on the opaque substrate 100 via a bonding wire 118. The P-type bonding pad 112 is located on the P-type transparent metal electrode 108 and electrically couples to a second electrode 116 patterned on the opaque substrate 100 via a bonding wire 120. The blue light emitting diode, N-type bonding pad 110, P-type bonding pad 112, and bonding wires 118 and 120 are covered by a mold resin 122, such as epoxy mold, to protect from being damaged by external force.

As the schematic top view of the conventional light emitting diode shown in FIG. 1B, the P-type mesa 106 is located on the square N-GaN 104. The P-type mesa 106 covers a portion of the square surface of the N-GaN 104, and the P-type transparent metal electrode 108 covers the upper surface of the P-type mesa 106 completely. The N-type bonding pad 110 and P-type bonding pad 112 are located on the diagonal of the square surface of the blue light emitting diode respectively.

The N-type bonding pad 110 and P-type bonding pad 112 must be disposed for electrical connecting to the N-GaN 104 and P-GaN 106 respectively, since the transparent sapphire substrate 102 is an electrical insulating substrate. The region of light emission is limited around the N-type and P-type bonding pads 110 and 112 due to the positions of the N-type bonding pad 110 and P-type bonding pad as the connection electrodes. Thus, the light emitting efficiency of the conventional blue light emitting diode package 10 is diminished since the light emitted from the light emitting diode is obstructed by the P-type bonding pad 112 composed of thick metal layer. The reflected light from the opaque substrate 100 is also diminished due to being obstructed by the N-type and P-type bonding pads 110 and 112. The thickness of the mold resin 122 also can not be reduced since the blue light emitting diode is placed on the opaque substrate 100 and the influence of the height of the bonding wires 118 and 120. Furthermore, it is necessary to cover a layer of fluorescent powder on the whole light emitting diode prior to forming the mold resin 122 for manufacturing the light emitting diode illuminating white light. Thus, the manufacturing process is more complicated.

Accordingly, it is an intention to provide an improved light emitting device package, which can overcome the above drawbacks.

### SUMMARY OF THE INVENTION

It is an objective of the present invention to provide a flip-chip like light emitting device package, in which a light emitting diode illuminating in the way like a flip-chip type die is placed in a recess of a transparent substrate. A thickness of a molding compound encapsulating the light emitting diode can be reduced. Hence, the total dimension of the flip-chip like light emitting device package can be reduced.

It is another objective of the present invention to provide a flip-chip like light emitting device package, in which a light emitting diode is placed in a recess of a transparent substrate, and the light from the light emitting diode emits downward toward the transparent substrate, like in a way a flip-chip type die illuminating. As a result, the emitting light is not obstructed with a bonding pad on the light emitting diode. The light-emitting area is enlarged, and the illuminating intensity of the flip-chip like light emitting device package is improved.

It is a further objective of the present invention to provide a flip-chip like light emitting device package, in which a bottom surface of a transparent substrate has an uneven portion underlying a light emitting diode placed in a recess of a top surface of the transparent substrate. Due to change of the refractive index at an interface of the bottom surface of the transparent substrate, an external quantum efficiency of the light emitting diode is improved, and a light emitting device with specific optical properties can be obtained.

It is still a further objective of the present invention to provide a flip-chip like light emitting device package, in which an adhesive material containing fluorescent powder is used for attaching a light emitting diode to a transparent substrate. As a result, the light emitting device package can illuminate white light or other light with wavelength longer than that of light illuminating from the light emitting diode itself.

It is still a further objective of the present invention to provide a flip-chip like light emitting device package, in which a light emitting diode emits light in a way like a flip-chip type die illuminates, and a conventional process can be used to attain this purpose.

In order to achieve the above objectives, the present invention provides a flip-chip like light emitting device package. The present flip-chip like light emitting device package comprises a transparent substrate having a first surface with a recess formed thereon, a light emitting diode, a first bonding pad, a second bonding pad, a first electrode, a second electrode, a first bonding wire, a second boning wire and a molding compound. The light emitting diode is placed in the recess of the transparent substrate and having a first semiconductor layer with a first conductivity and a second semiconductor layer with a second conductivity with opposite to the first conductivity adjacent to the first semiconductor layer. The transparent substrate does not absorb the light illuminating from the light emitting diode. The first bonding pad is formed on a surface of the light emitting diode and electrically coupling with the first semiconductor layer. The second bonding pad is formed on the surface of the light emitting diode and electrically coupling with the second semiconductor layer. The first electrode is formed on the first surface of the transparent substrate. The second electrode is formed on the first surface of the transparent substrate. The first bonding wire electrically couples between the first bonding pad and the first electrode. The second bonding wire electrically couples between the second bonding pad and the second electrode. The molding compound encapsulates the light emitting diode, the first bonding pad, the second bonding pad, the first bonding wire and the second bonding wire. The light emitting diode emits light toward the first surface of the transparent substrate, and thus not obstructed by the first bonding pad formed on the surface of the light emitting diode. The light-emitting area is enlarged, and the illuminating light is improved. In addition, the light emitting diode is placed in the recess of the transparent substrate such that the thickness of the molding compound can be reduced. And, the total dimension of the flip-chip like light emitting device package can be reduced.

### BRIEF DESCRIPTION OF THE DRAWINGS

The present invention can be best understood through the following description and accompanying drawings, wherein:

FIG. 1A is a schematic cross-sectional view of a conventional blue light emitting diode package;

FIG. 1B is a schematic top view of the conventional blue light emitting diode;

FIG. 2 is a schematic cross-sectional view of a flip-chip like light emitting device package according to a first preferred embodiment of the present invention;

FIG. 3 is a schematic cross-sectional view of a flip-chip like light emitting device package according to a second preferred embodiment of the present invention;

FIG. 4A is a schematic cross-sectional view of a flip-chip like light emitting device package according to a third preferred embodiment of the present invention;

FIG. 4B is a schematic bottom view of the flip-chip like light emitting device package of FIG. 4A;

FIG. 5A is a schematic cross-sectional view of a flip-chip like light emitting device package according to a fourth preferred embodiment of the present invention;

FIG. 5B is a schematic bottom view of the flip-chip like light emitting device package of FIG. 5A;

FIG. 6A is a schematic cross-sectional view of a flip-chip like light emitting device package according to a fifth preferred embodiment of the present invention; and

FIG. 6B is a schematic bottom view of the flip-chip like light emitting device package of FIG. 5A.

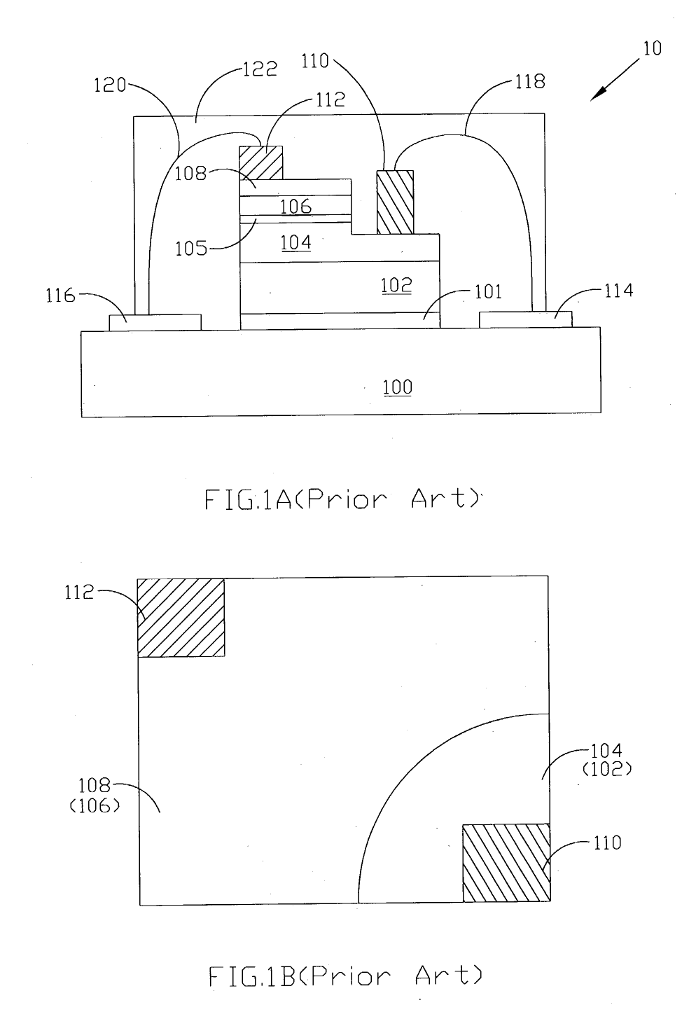

### DESCRIPTION OF THE PREFERRED EMBODIMENTS

The present invention provides a flip-chip like light emitting device package, which can be applied to light emitting diodes being able to emit light with different wavelengths respectively. A light emitting device is faced down and placed in a recess of a transparent substrate in order that the light emitting device emits light toward the transparent substrate, which is like a way a flip-chip type die illuminates. And, the light emitted from the light emitting device is not obstructed by a bonding pad disposed thereon for providing electrical connection between the light emitting device and one electrode patterned on the transparent substrate. The light emitting area is thus not limited thereto and can be enlarged. The illuminating intensity of the flip-chip like light emitting device package can be improved. Moreover, since the flip-chip like light emitting device is placed in the recess of the transparent substrate, a thickness of a molding compound for encapsulating the flip-chip like light emitting device can be reduced so as to reduce the total dimension of the flip-chip like light emitting device package.

The present invention will be described in detail in accordance with the following preferred embodiments with reference to accompanying drawings.

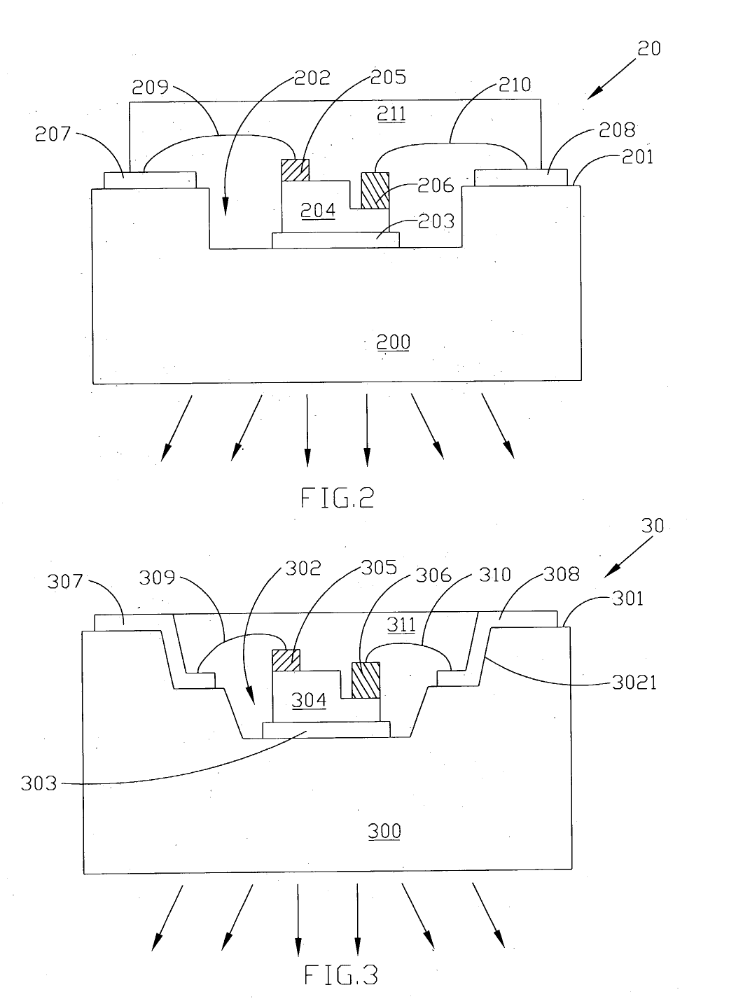

FIG. 2 is a schematic cross-sectional view of a flip-chip like light emitting device package 20 according to a first preferred embodiment of the present invention. The flip-chip like light emitting device package 20 comprises a transparent substrate 200 having a first surface 201 with a recess 202 formed thereon, a light emitting diode 204, a first bonding pad 205, a second bonding pad 206, a first electrode 207, a second electrode 208, a first bonding wire 209, a second bonding wire 210, and a molding compound 211. The material of the transparent substrate 200 can be selected from a group consisting of glass, quartz, epoxy, acrylonitrile butadiene styrene copolymer resin (ABS resin), polymethyl methacrylate (PMMA), sapphire, or thermal plastics such as polysulfones, polyethersulfones, polyetherimides, polyimides, polyamide-imide, polyphenylene sulfide and silicon-carbon thermosets. The light emitting diode 204 is placed in the recess 202 of the transparent substrate 200. The light emitting diode 204 has a first semiconductor layer (not shown) with a first conductivity and a second semiconductor layer (not shown) with a second conductivity with opposite to the first conductivity joining to the first semiconductor layer. The light emitting diode 204 can emit light with different wavelengths depending on the semiconductor materials used. And, the transparent substrate 200 has a property that does not absorb the light emitting from the light emitting diode 204. It is preferable that the recess 202 of the transparent substrate 200 comprises a flat surface for placing the light emitting diode 204. Since the light emitting diode 204 is faced down and placed in the recess 202 of the transparent substrate 200, the light emitting diode 204 would emit light toward the first surface 201 of the transparent substrate 200 in a way like a flip-chip type die illuminates. An adhesive material 203, such as epoxy, can be used to attach the light emitting diode 204 to the transparent substrate 200. In addition, the adhesive material 203 can contain fluorescent powder, for example the fluorescent powder can blend into epoxy, making the flip-chip type light emitting device package 20 to emit white light or other light with a wavelength shorter than the light from the light emitting diode 204.

The first bonding pad 205 is formed on a surface of the light emitting diode 204 and electrically coupling with the first semiconductor layer thereof. The second bonding pad 206 is formed on the surface of the light emitting diode 204 and electrically coupling with the second semiconductor layer thereof. The materials of the first bonding pad 205 and second bonding pad 206 include metal, and the first bonding pad 205 and second bonding pad 206 can be composed of two or more layers. The first electrode 207 is formed on the first surface 201 of the transparent substrate 200 and a first bonding wire 209 electrically couples between the first bonding pad 205 and the first electrode 207. The second electrode 208 is formed on the first surface 201 of the transparent substrate 200 and a second bonding wire 210 electrically couples between the second bonding pad 206 and the second electrode 208. The first electrode 207 and second electrode 208 can be formed on the transparent substrate 200 by patterning a metal layer formed thereon, for example, by a photolithography and etching method, vaporized sputtering or electroplating. The first bonding wire 209 and second bonding wire 210 can be made of gold or aluminum. The molding compound 211, such as epoxy, is molded to form a shielding for encapsulating the light emitting diode 204, the first bonding pad 205, the second bonding pad 206, the first bonding wire 209 and the second bonding wire 210.

FIG. 3 is a schematic cross-sectional view of a flip-chip like light emitting device package 30 according to a second preferred embodiment of the present invention. The flip-chip like light emitting device package 30 comprises a transparent substrate 300 having a first surface 301 with a recess 302 formed thereon, a light emitting diode 304, a first bonding pad 305, a second bonding pad 306, a first electrode 307, a second electrode 308, a first bonding wire 309, a second bonding wire 310 and a molding compound 311. The transparent substrate 300 has a property that does not absorb the light from the light emitting diode 304. The elements of the light emitting device package 30 are the same with those of the flip-chip type light emitting device package 20 of the first preferred embodiment except for the structure of the recess 302 of the transparent substrate 300. Referring to FIG.3, the recess 302 of the transparent substrate 300 includes a step-shaped sidewall 3021, for example a two-step sidewall, and portions of the first electrode 307 and second electrode 308 are disposed along the step-shaped sidewall 3021 respectively. Hence, the thickness of the molding compound 311 can be further reduced, and the total dimension of the flip-chip like light emitting device package 30 can be further reduced. In addition, the adhesive material 303 can contain fluorescent powder, for example the fluorescent powder can blend into epoxy, making the flip-chip like light emitting device package 30 to emit white light or other light with a wavelength shorter than the light from the light emitting diode 304.

In addition, the bottom surface of the transparent substrate can be processed to provide specific optical properties by way of injection or molding so as to increase the external quantum effect of the light emitting device or additional optical properties.

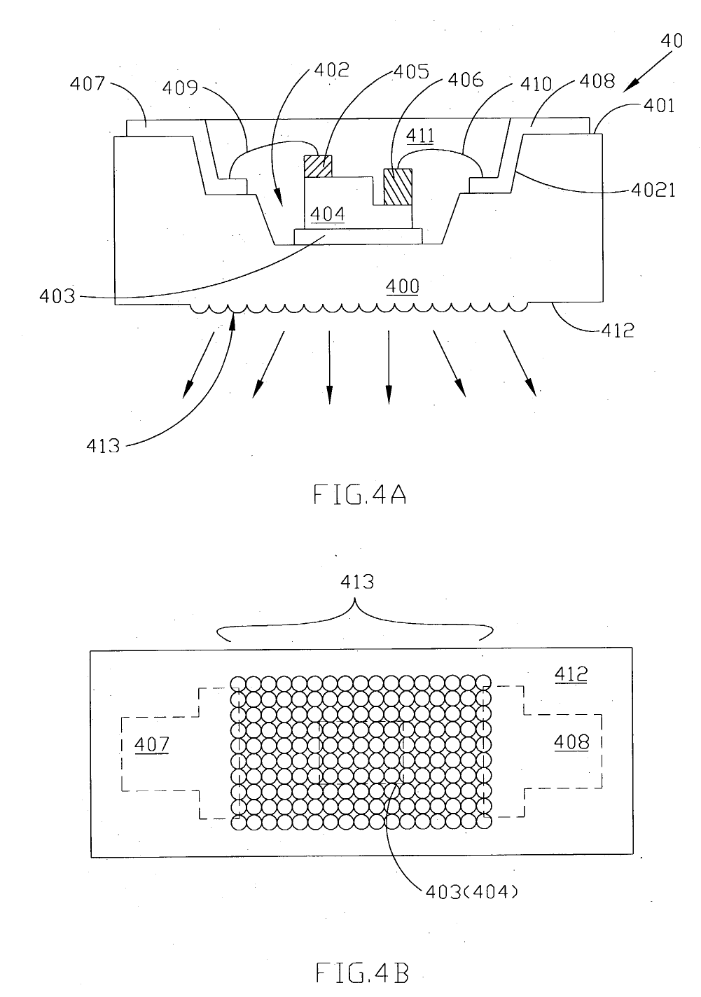

FIG. 4A is a schematic cross-sectional view of a flip-chip like light emitting device package 40 according to a third preferred embodiment of the present invention, and FIG. 4B is a schematic bottom view of the flip-chip like light emitting device package 40. The flip-chip like light emitting device package 40 comprises a transparent substrate 400, a light emitting diode 404, a first bonding pad 405, a second bonding pad 406, a first electrode 407, a second electrode 408, a first bonding wire 409, a second bonding wire 410 and a molding compound 411. The transparent substrate 400 includes a first surface 401 having a recess 402 with a step-shaped sidewall 4021 and a second surface 412 having an uneven portion 413 underlying the light emitting diode 404. And, the transparent substrate 400 does not absorb the light from the light emitting diode 404. The elements of the flip-chip like light emitting device package 40 are the same with those of the flip-chip like light emitting device package 30 except that there is the uneven portion 413 formed on the second surface 412 of the transparent substrate 400. As shown in FIG. 4B, an uneven portion formed of a plurality of semi-spheres is formed on the second surface 412 of the transparent substrate 400 underlying the light emitting diode 404. The uneven portion 413 of the second surface 412 of the transparent substrate 400 prevents the light emitted from the light emitting diode 404 from totally reflection in interior due to the change of the refractive index at the interface of the uneven portion 413. As a result, the external quantum efficiency of the light emitting device package 40 can be improved. Moreover, the semi-spheres formed on the uneven portion 413 of the second surface 412 provide a light-concentrated effect. The illuminating intensity of the flip-chip like light emitting device package 40 is thus improved.

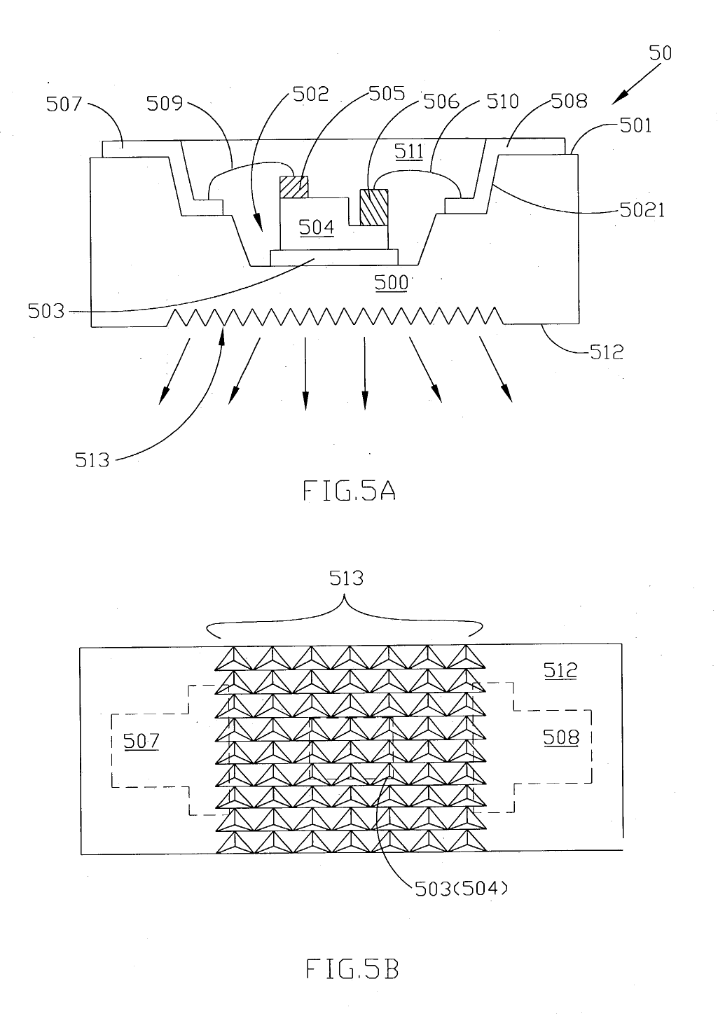

FIG. 5A is a schematic cross-sectional view of a flip-chip like light emitting device package 50 according to a fourth preferred embodiment of the present invention, and FIG. 5B is a schematic bottom view of the flip-chip like light emitting device package 50. The flip-chip like light emitting device package 50 comprises a transparent substrate 500, a light emitting diode 504, a first bonding pad 505, a second bonding pad 506, a first electrode 507, a second electrode 508, a first bonding wire 509, a second bonding wire 510 and a molding compound 511. The transparent substrate 500 includes a first surface 501 having a recess 502 with a step-shaped sidewall 5021 and a second surface 512 having an uneven portion 513 underlying the light emitting diode 504. And, the transparent substrate 500 does not absorb the light from the light emitting diode 504. The elements of the flip-chip like light emitting device package 50 are the same with those of the flip-chip like light emitting device package 40 except that the uneven portion 513 of the transparent substrate 500 is formed of a plurality of triangular bodies. Like the third preferred embodiment, the fourth preferred embodiment also has a property for improving external quantum effect. Moreover, referring to FIGS. 5A and 5B, the triangular bodies of the uneven portion 513 of the transparent substrate 500 can provide a specific optical directionality from a far view. The triangular bodies can be instead by any polygonal body, even parabola-shaped body, so as to satisfy the requirement of specific optical directionality.

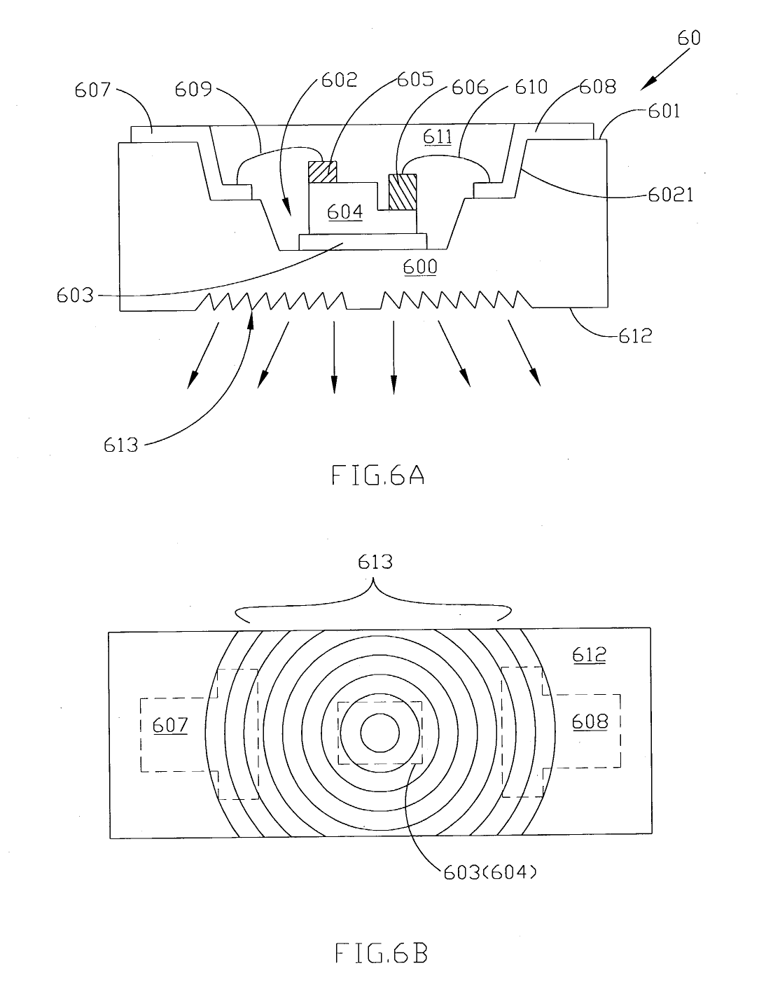

FIG. 6A is a schematic cross-sectional view of a flip-chip like light emitting device package 60 according to a third preferred embodiment of the present invention, and FIG. 6B is a schematic bottom view of the flip-chip like light emitting device package 60. The flip-chip like light emitting device package 60 comprises a transparent substrate 600, a light emitting diode 604, a first bonding pad 605, a second bonding pad 606, a first electrode 607, a second electrode 608, a first bonding wire 609, a second bonding wire 610 and a molding compound 611. The transparent substrate 600 includes a first surface 601 having a recess 602 with a step-shaped sidewall 6021 and a second surface 612 having an uneven portion 613 underlying the light emitting diode 604. And, the transparent substrate 600 does not absorb the light from the light emitting diode 604. The elements of the flip-chip like light emitting device package 60 are the same with those of the flip-chip like light emitting device package 40 except that the uneven portion 613 is formed of concentric circles. Referring to FIG. 6B, the uneven portion 613 of the second surface 612 of the transparent substrate 600 makes the light emitted from the light emitting diode 604 being less internally reflected and absorbed by the transparent substrate 600 due to the change of the refractive index at the interface of the uneven portion 613. As a result, the external quantum efficiency of the light emitting device package 60 can be improved. Moreover, based on the refractive index of the material of the transparent substrate 600 and the angle provided between the concentric circles and the second surface 612 of the transparent substrate 600, the light emitting device can be designed to provide properties such as concentrating light, dispersing light, illuminating parallel light or other optical properties.

Alternately, the flip-chip like light emitting device package 20 can be modified in accordance with the third preferred embodiment to the fifth preferred embodiment to form an uneven portion on the bottom surface of the transparent substrate 200.

In accordance with the flip-chip like light emitting device package provided by the present invention, the light from the e light emitting diode emits downward toward the transparent substrate like a way a flip-chip type die illuminating. The emitting light is not obstructed with the bonding pad disposed on the light emitting diode, the light-emitting area is enlarged and thus the illuminating intensity is improved. In addition, the light emitting diode is placed in the recess of the transparent substrate, the thickness of the molding compound thus can be reduced, and the total dimension of the flip-chip like light emitting device package is also reduced.

The preferred embodiments are only used to illustrate the present invention, not intended to limit the scope thereof. Many modifications of the preferred embodiments can be made without departing from the spirit of the present invention.

What is claimed is:

1. A flip-chip like light emitting device package, comprising:
a transparent substrate having a first surface with a recess formed thereon;
a light emitting diode placed in said recess of said transparent substrate, said light emitting diode having a first semiconductor layer with a first conductivity and a second semiconductor layer with a second conductivity with opposite to said first conductivity joining to said first semiconductor layer, and the light emitting from said light emitting diode being not absorbed by said transparent substrate;
a first bonding pad formed on a surface of said light emitting diode and electrically coupling with said first semiconductor layer;
a second bonding pad formed on said surface of said light emitting diode the same with said first bonding pad and electrically coupling with said second semiconductor layer;
a first electrode formed on said first surface of said transparent substrate;
a second electrode formed on said first surface of said transparent substrate;
a first bonding wire electrically coupling between said first bonding pad and said first electrode;
a second bonding wire electrically coupling between said second bonding pad and said second electrode; and
a molding compound for encapsulating said light emitting diode, said first bonding pad, said second bonding pad, said first bonding wire and said second bonding wire.

2. The flip-chip like light emitting device package of claim 1, wherein further comprising an adhesive material adhering said light emitting diode to said recess of said transparent substrate.

3. The flip-chip like light emitting device package of claim 1, wherein said recess of said transparent substrate comprises a step-type sidewall, and portions of said first electrode and said second electrode respectively formed on said step-shaped sidewall.

4. The flip-chip like light emitting device package of claim 2, wherein said recess of said transparent substrate comprises a step-type sidewall, and portions of said first electrode and said second electrode respectively formed on said step-shaped sidewall.

5. The flip-chip like light emitting device package of claim 1, wherein said transparent substrate comprises a second surface having an uneven portion underlying said light emitting diode.

6. The flip-chip like light emitting device package of claim 2, wherein said transparent substrate comprises a second surface having an uneven portion underlying said light emitting diode.

7. The flip-chip like light emitting device package of claim 5, wherein said uneven portion of said second surface of said transparent substrate comprises a concentric circle profile.

8. The flip-chip like light emitting device package of claim 6, wherein said uneven portion of said second surface of said transparent substrate comprises a concentric circle profile.

9. The flip-chip like light emitting device package of claim 5, wherein said uneven portion of said second surface of said transparent substrate comprises a profile consisting of a plurality of semi-spheres.

10. The flip-chip like light emitting device package of claim 6, wherein said uneven portion of said second surface of said transparent substrate comprises a profile consisting of a plurality of semi-spheres.

11. The flip-chip like light emitting device package of claim 5, wherein said uneven portion of said second surface of said transparent substrate comprises a profile consisting of a plurality of polygonal bodies.

12. The flip-chip like light emitting device package of claim 6, wherein said uneven portion of said second surface of said transparent substrate comprises a profile consisting of a plurality of polygonal bodies.

13. The flip-chip like light emitting device package of claim 11, wherein said polygonal body is a triangular body.

14. The flip-chip like light emitting device package of claim 12, wherein said polygonal body is a triangular body.

15. The flip-chip like light emitting device package of claim 1, wherein the material of said transparent substrate is selected from a group consisting of glass, quartz, epoxy, acrylonitrile butadiene styrene copolymer resin (ABS resin), polymethyl methacrylate (PMMA), sapphire, polysulfones, polyethersulfones, polyetherimides, polyimides, polyamide-imide, polyphenylene sulfide and silicon-carbon thermosets.

16. The flip-chip like light emitting device package of claim 2, wherein the material of said transparent substrate is selected from a group consisting of glass, quartz, epoxy, acrylonitrile butadiene styrene copolymer resin (ABS resin), polymethyl methacrylate (PMMA), sapphire, polysulfones, polyethersulfones, polyetherimides, polyimides, polyamide-imide, polyphenylene sulfide and silicon-carbon thermosets.

17. The flip-chip like light emitting device package of claim 2, wherein said adhesive material further comprises fluorescent powder.

18. The flip-chip like light emitting device package of claim 17, wherein said recess of said transparent substrate comprises a step-type sidewall, and portions of said first electrode and said second electrode formed on said step-shaped sidewall.

19. The flip-chip like light emitting device package of claim 17, wherein the material of said transparent substrate is selected from a group consisting of glass, quartz, epoxy, acrylonitrile butadiene styrene copolymer resin (ABS resin), polymethyl methacrylate (PMMA), sapphire, polysulfones, polyethersulfones, polyetherimides, polyimides, polyamide-imide, polyphenylene sulfide and silicon-carbon thermosets.

20. The flip-chip like light emitting device package of claim 18, wherein the material of said transparent substrate is selected from a group consisting of glass, quartz, epoxy, acrylonitrile butadiene styrene copolymer resin (ABS resin), polymethyl methacrylate (PMMA), sapphire polysulfones, polyethersulfones, polyetherimides, polyimides, polyamide-imide, polyphenylene sulfide and silicon-carbon thermosets.
